(19) United States
(12) Patent Application Publication
(10) Pub. No.: US 2005/0229856 A1
(43) Pub. Date: Oct. 20, 2005

(54) Means and method for a liquid metal evaporation source with integral level sensor and external reservoir

(76) Inventor: Roger J. Malik, Warren, NJ (US)

Correspondence Address: Ward & Olivo, 708 Third Avenue, New York, NY, 10017, US

(21) Appl. No.: 10/829,148

(22) Filed: Apr. 20, 2004

(51) Int. Cl. C23C 16/00

(52) U.S. Cl. 118/726

(57) ABSTRACT

A liquid metal evaporation source for use in Molecular Beam Epitaxy and related metal vacuum deposition techniques. An evaporator is maintained at a high temperature to evaporate a liquid metal, a reservoir for holding the liquid metal source is maintained at a temperature above the melting point of the metal but below the temperature in the evaporator, and a hollow transport tube connecting the evaporator and reservoir is maintained at a temperature between these temperatures. The reservoir is in the shape of a hollow cylinder with a close-fitting cylindrical piston which is used to force the liquid metal through the hollow transport tube into the evaporator. The liquid metal will not flow past the piston seal if a suitably small gap is formed between the piston and the reservoir walls wherein the surface tension of the liquid metal will exceed its hydrostatic pressure against the piston thus forming a leak-tight seal.

This invention was made with government support under contract F33615-98-C-1212 awarded by Air Force Research Laboratory. The government has certain right in the invention.

### TECHNICAL FIELD OF THE INVENTION

The present invention relates generally to methods and apparatus for the deposition or growth of thin films upon a substrate. More particularly, the invention pertains to method and apparatus for a liquid metal evaporation source for use in molecular beam epitaxy (MBE) and other epitaxy and deposition techniques predominantly used in semiconductor technology.

### BACKGROUND OF THE INVENTION

The evaporation of metals in vacuum systems is widely used in industrial applications to form reflective and/or protective metal coatings. Evaporation of liquid metals such as Gallium (Ga), Indium (In), and Aluminum (Al) under ultra-high vacuum conditions in Molecular Beam Epitaxy (MBE) is also used in the growth of compound semiconductors such as Gallium Arsenide (GaAs) and Indium Phosphide (InP) and related materials. These thin semiconductor layers are used to fabricate a variety of technologically important electronic and optoelectronic devices such as microwave transistors, optical detectors and lasers.

These techniques are used in the manufacture of, among other things, compound semiconductors. Compound semiconductors are crystalline semiconductor materials made from a chemical compound using elements from groups III and V or groups IIB and VI of the periodic table, such that the compounds are isoelectronic with the elemental semiconductors (e.g., silicon and germanium from group IV). In addition, the resulting compounds have similar semi-conducting properties to silicon, though some important practical differences arise that enable use of these materials in the manufacture of special electronic devices and integrated circuits.

Compound semiconductors are generally characterized by a direct energy gap, which permits radiative transitions between conduction and valence bands to occur, resulting in the emission of electromagnetic radiation. The wavelength of the radiation is related to the energy band gap, and the compound semiconductors can be alloyed to produce the appropriate band gaps for emission of visible light, or infrared radiation for optical communications. These materials are therefore used for light emitting diodes (LEDs), semiconductor lasers, etc. GaAs and InP are also used in microwave devices and integrated circuits, including transferred electron devices, high electron mobility transistors (HEMT), and heterojunction bipolar transistors (HBT).

Epitaxy is a method of growing a thin layer of material upon a single-crystal substrate, such as silicon, so that the crystal structure of the layer is identical to that of the substrate. The material, which may be the same as the substrate or a different one, is usually deposited from a gaseous mixture (i.e., vapor phase epitaxy) but also may be deposited from a liquid mixture (i.e., liquid phase epitaxy). These techniques are extensively used in semiconductor technology when a layer (the epitaxial layer) of different conductivity or band gap than the substrate is required.

Vapor phase epitaxy (VPE), a form of chemical vapor deposition (CVD), is the most common method of epitaxy. For VPE, the material to be deposited on the substrate is heated to its gaseous state in a furnace also containing the substrate material. While the substrate material is held at a temperature just below its solidification point, the gas molecules reach the substrate and are deposited on its surface, thereby replicating the substrate crystal structure. The conditions in the furnace can typically be adjusted with respect to temperature and pressure to allow particular desired combinations of substrate and deposited material to be produced.

For example, the deposition rate is governed by the temperature of the sample and the pressure of the reactant gases inside the reactor. These parameters can also affect the quality of the resulting epitaxial layer, in terms of chemical purity and number of defects present in the crystalline film. In VPE, the reactants and conditions are chosen to enable the reaction at the semiconductor surface to produce a layer following the crystalline ordering of the underlying layer.

Often the reactants are inorganic materials, though recently the use of organic compounds containing metal atoms has been employed for VPE of compound semiconductors—otherwise known as organo-metallic vapor phase epitaxy (OMVPE). Generally, these reactions are carried out at reduced pressure, and the process is called low pressure chemical vapor deposition (LPCVD). Also, faster deposition occurs at higher pressures, and some processes can take place at atmospheric pressure; atmospheric pressure chemical vapor deposition (APCVD). Reaction rates can also be increased by using energetic reactant gases. For example, the use of a glow discharge or plasma at low pressure to provide highly energetic and reactive species is employed in plasma enhanced chemical vapor deposition (PECVD).

Similar to VPE, liquid phase epitaxy (LPE) is a method of growing an epitaxial layer on a substrate, but from a molten material. With LPE the substrate is placed in, for example, a slider while the material to be deposited is contained in molten form in, for example, a graphite “boat”. The molten material is supercooled to just below the solidification temperature, while the slider containing the substrate is moved slowly across its surface. Atoms of the molten material then solidify onto the substrate. This particular method of epitaxy is most useful for III-V or II-VI compound semiconductors, such as gallium arsenide substrates. LPE, however, has its limitations (e.g., LPE cannot produce very thin high-quality layers, etc.), but is inexpensive and capable of growing many material compositions. LPE is therefore still used in the manufacture of some devices, such as light-emitting diodes, that do not require such thin uniform high-quality layers.

Of particular use in semiconductor technology is the growth process of Molecular Beam Epitaxy (MBE). MBE is a growth process involving the deposition of thin films of material onto a heated substrate in a vacuum by directing molecular or atomic beams onto the substrate. Deposited atoms and molecules then migrate to their energetically preferred lattice positions on a heated substrate, thus, yielding film growth of high crystalline quality and optimum thickness uniformity. MBE is widely used in the research, development, and manufacture of compound semiconductors, as well as for thin-film deposition of elemental semiconductors, metals and insulating layers. Under suitable conditions the MBE process can be controlled to produce almost any required epitaxial layer composition, thickness and doping level with a resolution of virtually one atomic layer, to a high degree of accuracy and uniformity across a substrate wafer. Of course, MBE has its disadvantages, such as the high-vacuum requirements, complex and costly equipment, and the slow growth rate of the epitaxial layer.

A principal apparatus utilized in MBE deposition is the thermal effusion cell having a crucible, which contains the effusion material, for example gallium, arsenic, or other elements or compounds. During the MBE process, the crucible is heated to vaporize and effuse the material out of the crucible through an orifice into an ultra high vacuum growth chamber for deposition onto the heated substrate, which is located in the growth chamber. Typically, one or more cells are actuated in the growth chamber and generate a beam which is directed at a predetermined angle toward the substrate which is mounted on a rotating substrate holder. Control of the beam is typically accomplished via shutters and/or valves. During use, various preparatory procedures are first performed on the substrate. Then, the cells are powered up, heated and unshuttered. Finally, the desired epitaxial deposition is accomplished on the heated, rotating substrate. After growth is completed, the epitaxial wafer is cooled and removed from the chamber.

Conventional source crucibles are constructed of an inert refractory material, such as pyrolytic boron nitride (PBN), which is stable at high effusion temperatures. The crucibles are typically formed by a CVD process utilizing a forming graphite mandrel in a deposition chamber. In the past, various crucible designs and configurations have been used in the MBE process. However, these prior art crucibles have significant limitations. The primary problems associated with existing crucibles are (1) low capacity, (2) lack of uniformity, (3) oval defect production, (4) short term flux transients, (5) long term flux transients, etc.

The amount of material a crucible may hold for a particular MBE process is its capacity. Greater capacity permits construction of larger and/or a greater number of devices per load of source material in the crucible. The desired capacity has been achieved in some designs by utilizing a straight-wall, cylindrical configuration. However, crucibles having a cylindrical configuration throughout tend to provide poor depositional uniformity because the molecular beam emitted from the zero draft cylindrical orifice is too tightly focused or collimated upon the substrate holder.

Next, uniformity relates primarily to the uniformity of the thickness of the layers deposited over the target substrate area via the material emitted from the orifice of the crucible but may also be compositional in nature. Uniformity has been achieved in some conventional designs by utilizing a conically configured crucible body having a positive draft. However, crucibles having a conical configuration have limited capacity, exhibit depletion effects, and are prone to flux transients (the volume of a cone is only ⅓ the volume of a cylinder with the same height and base area).

Morphological defects present on the formed semiconductor device are called oval defects. Source-related oval defects are thought to be caused by “spitting” from the material melt at the crucible base which occurs when droplets of condensed material form at the crucible orifice (due to a reduced temperature in the orifice region) and then roll back into the melt. Oval defect production has been reduced in some designs by heating the orifice or lip of the crucible to prevent the material condensation, commonly referred to as “hot lip” devices. A disadvantage with some hot lip source designs is that they produce a hydrodynamically unstable flux, they tend to produce undesirable levels of impurities due to enhanced outgassing, and they often exhibit rapid depletion effects.

Lastly, short term or shutter-related flux transients are changes in the effusion rate over time due to the activation of the source shutter, which causes radiational cooling of the crucible while long term flux transients are changes in effusion rate over time due to decreases in the surface area of the melt. Generally, flux transients are a problem in crucible designs having a conical configuration throughout.

Numerous known crucibles are well suited for use in an MBE effusion cell. For example, a typical MBE effusion cell, generally would comprise a head assembly and a mounting flange and support assembly. The mounting flange and support assembly couples the effusion cell to an MBE growth chamber and supports the head assembly at a predetermined position within the growth chamber. The crucible is preferably constructed of PBN and has a conical configuration with an outwardly oriented orifice having an annular lip. The effusion cell may include various optional features such as an integral shutter, an integral water cooling system, and the like.

Another type of apparatus utilized in MBE processes is the gas plasma source or emitter. Gas plasma sources have a plasma chamber with a gas inlet attached at one end for input of a gas such as Nitrogen into the chamber. A high frequency RF coil or plate is then used to crack the gas and form an active species, for example, atomic Nitrogen, which is effused through an output end, typically disposed opposite the gas inlet end. The output end of the emitter typically has one or more apertures. The effused species egresses through the output end apertures into an ultra-high vacuum growth chamber where the species combines with other elements or compounds. An example of this process is a Nitrogen gas plasma source used to generate non-ionized N₁ to subsequently yield Gallium Nitride in the growth chamber.

Prior art plasma chambers are typically multi-piece structures. The various components of the structure are typically constructed of pyrolytic boron nitride (PBN). These multi-piece chamber structures have significant limitations. A primary problem is that they are prone to leaking when under gas pressure during operation. Leaking gas will not be cracked by the source and this results in a loss of efficiency. Other problems found in prior art sources include generation of instabilities, high levels of N₂ gas in the growth environment, and low levels of N₁.

One solution to these problems has been to use quartz to form the chamber because quartz can be shaped into a one piece design. However, for some high temperature applications, such as growth of Gallium Nitride crystals, the quartz tube can melt and lose its shape. Also, quartz can contribute undesirable Oxygen (O) and Silicon (Si) gas into the growth environment

With MBE, elemental arsenic and phosphorous are often heated to obtain the species necessary to grow the desired semiconductor layers. However, the species of arsenic, i.e., As₄, derived from heating elemental arsenic or phosphorous are difficult to handle and the tetramer form leads to point defects or regions of high phosphorous or arsenic concentrations in the growing layer. To avoid these problems, phosphine, PH₃, and arsine, AsH₃, have been used in CVD and MBE growth processes. These materials are generally broken down into smaller molecules or components by heating the molecule above its bond breaking temperature, i.e., “cracked” into useful species of P₂ and As₂ by passing them through a heated zone to liberate the hydrogen as H₂ gas. The process of using the gas in a heated atmosphere to break down the arsine and phosphine is generally referred to as thermal cracking. Thermal cracking aims at the reduction of molecular size by application of heat without any additional sophistication such as catalyst or hydrogen.

Thermal cracking is achieved in MBE processes through the use of a thermal cracker. A thermal cracker is typically used for materials, like arsenic, where it is desirable after evaporation of the source material to further crack the molecules of the source material. Cracking effusion devices first sublimate solid source material and then “crack” it, that is, convert the vaporous material to smaller atomic species by subjecting it to extremely high temperatures. A thermal cracker typically has two or more thermal zones. The crucible of a two zone cracker generally has a large body portion located in the first, lower temperature zone and a smaller diameter cracking portion extending through the second, higher temperature zone. The source material is placed in the body portion, where it is heated, causing the material to evaporate and effuse into the cracking portion. The higher temperature in the second zone (or cracking portion) causes the source material to crack as it passes therethrough. The cracked material then effuses out of the exit orifice, where it is deposited onto the substrate.

Because of the inwardly directed transition area between the body portion and the cracking portion of the crucible used in such thermal crackers, it was not possible to make such crucibles for crackers out of PBN. Instead, these crucibles are typically made out of a weldable metal such as tantalum or titanium. This severely limited the types of source materials which could be used in a thermal cracker, because the tantalum or titanium crucible is not suitable for use with liquid metal source materials, such as Silver (Ag), Aluminum (Al), Gold (Au), Boron (B), Barium (Ba), Bismuth (Bi), Cadmium (Cd), Cobolt (Co), Cesium (Cs), Copper (Cu), Iron (Fe), Gallium (Ga), Gadolinium (Gd), Germanium (Ge), Mercury (Hg), Indium (In), Potassium (K), Lanthanum (La), Lithium (Li), Sodium (Na), Nickel (Ni), Lead (Pb), Palladium (Pd), Praseodymium (Pr), Platinum (Pt), Rubidium (Rb), Antimony (Sb), Scandium (Sc), Selenium (Se), Silicon (Si), Tin (Sn), Tellurium (Te), Thallium (Tl), Vanadium (V), Ytterbium (Y), and Zinc (Zn).

In MBE, molecular beams of certain elements, such as pure phosphorus, are directed onto the surface of a substrate, where they react with each other to create a layer with the desired properties used to construct complex semi-conducting structures. Phosphorus effusion devices are constructed using either a one or two chamber design. In a single chamber design, solid red phosphorus is sublimated at about 300 Celsius (C) in a furnace or crucible, which is vacuum evacuated. When the red phosphorus is sublimated, it produces both red phosphorus vapor and white phosphorus vapor, which is then introduced to the phosphorus cracker by a valve before being directed to the substrate.

Such a single chamber design suffers from at least one drawback. In particular, some of the vaporous white phosphorus condenses on the walls of the chamber. At an operating temperature of 300 C, the vapor pressure of white phosphorus is significantly higher than that of red phosphorus. As a result, when the valve is closed, a large pressure build-up occurs in the chamber. When the valve is then opened to the cracker, pressure bursts occur into the MBE chamber. The excess release of phosphorus into the MBE chamber is harmful to the MBE growth system. In addition, the MBE chamber requires several hours after such a pressure burst to recover to a proper working pressure.

To reduce this problem, it has been proposed to add a second chamber to the system design. The vaporous white phosphorus is purposefully condensed in a second chamber so that it deposits on the walls of the second chamber. This second chamber is independently temperature regulated so that the walls are cooler to encourage the white phosphorus condensation, which significantly reduces the vapor pressure within the second chamber. A valve admits the vaporous phosphorus to the cracker where P₄ phosphorus is converted to P₂ phosphorus.

A critical requirement in MBE growth is the need to precisely control the metal evaporation rates to reproducibly grow thin semiconductor layers with precise thickness and compositions. In addition, the metal evaporation rates must be controlled to within 0.5 percent in order to obtain lattice-matching of ternary and quaternary alloys on host substrates (for example In_{0.532}Ga_{0.478}As and In_{0.521}Al_{0.479}As on InP substrates). In conventional MBE systems, metals are usually evaporated in heated crucibles that are conical in shape to achieve thickness and compositional uniformity in the deposited films over large rotating substrates or multiple substrate holding platens. (See for example, Parker, Herman, etc. regarding MBE technology). The molecular beam fluxes emanating from the crucible and incident upon the substrate can be approximated by the Knudsen effusion equation that is given by:

$$J ( T ) = \frac{AP ( T ) Cos Φ}{{{pd}^{ 2} ( MT )}^{1 / 2}} \qquad Equation ( 1 )$$

where J(T) is the molecular flux density incident upon the substrate in units of cm⁻²s⁻¹, T is the absolute temperature in Kelvin (K), A is the area of the liquid metal surface in cm², P(T) is the metal vapor pressure of the element in Torr, d is the distance between the metal surface and the substrate in cm, M is the molecular weight of the metal in gram-mole⁻¹, and Φ is the angle between the normal to the substrate surface and the metal crucible axis.

The geometry of a prior art conical crucible evaporation source is shown in FIG. 1. A conical crucible 10 preferably made from Pyrolytic Boron Nitride (PBN) or Pyrolytic Graphite (PG) is radiantly heated by a resistive heater element 18. The crucible temperature is sensed and controlled by a thermocouple 17 to establish a desired evaporation rate of the metal atoms upon the substrate. It is seen that the taper angle of the conical crucible 104 enables the substrate holder 11 heated by a resistive heating element 16 to be exposed to the entire evaporation surface of the metal to provide uniform coating of the metal film through rotation of the substrate 19. The conical crucible taper angle 104 prevents shadowing of the substrate by the crucible walls as the liquid metal is depleted in the crucible over time through evaporation of the metal. The initial surface area of the metal 12 is reduced over time due to metal depletion to a final surface area 13. The distance of the metal surface to the substrate also increases from an initial distance 15 to a final distance 14.

The depletion effect of the metal in the conical crucible leads to a decrease in the metal evaporation rate impinging upon the substrate (at a fixed crucible temperature) over time due to two geometrical effects. The first geometrical effect is that the evaporation surface area A is decreased due to metal depletion leading to a reduction in evaporation rate at a fixed evaporation temperature as given in Equation 1. The reduction in the surface area of the metal from an initial area 20 at initial time to t₀ a reduced area 21 at a later time t₁ is illustrated in FIG. 2. The shape of the metal surface area is elliptical since the crucible is normally tilted at an angle to the substrate surface normal as shown in FIG. 1. The second geometrical effect is that the distance d between the metal evaporation source and the substrate also increases due to depletion of the metal source which again leads to a reduction of evaporation rate at a fixed evaporation temperature as given in Equation 1. The principle of the second geometrical effect has been reported in Jones et al. “Linear Motion Oven for Variable Incident Group III Flux” J.Vac.Sci.Technol. B 13(2) March/April 1995, which discloses an MBE effusion cell with an adjustable source-to-substrate distance to mechanically adjust the evaporation rate. Although this method may be useful in some circumstances, there is a limited practical range over which this distance can be adjusted.

In order to maintain a constant metal evaporation rate upon the substrate, the crucible temperature must be gradually increased with time to compensate for the reduction in metal surface area A and increased source-to-substrate distance d. As given in Equation 1, the increase in cell temperature leads to an increase in the vapor pressure of the metal P(T) to offset the decrease of A and the increase in d. This requires a time-consuming and tedious re-calibration procedure that is normally performed daily in the MBE growth process. Errors in flux measurement can result in layer thickness and compositions that do not meet specifications that adversely affect wafer yields. In addition, the metal fluxes cannot be measured in real-time during the MBE growth process leading to further errors and decreased wafer yields. Lattice-matching of semiconductor layers becomes problematic near the end of the life of the source charges as the metal surface areas reach a minimum area resulting in rapid changes in metal evaporation rates with time.

Several metal evaporator designs have been used to overcome the problem of the reduction in surface area in conical crucible evaporation sources due to metal depletion. One such example, shown in FIG. 3, exhibits low flux transient behavior as shutters of individual furnaces are opened to initiate the process and with excellent flux uniformity over the surface being processed and over the processing time. Here, the crucible is designed for liquid melts of Group III metals, including Gallium, Indium, and Aluminum, and comprises a two member construction in which the outer member (i.e., containing the melt) is generally cylindrical and of maximum capacity consistent with the furnace interior, and the inner member has a conical configuration with a small aperture at the bottom for optimum molecular beam formation. The conical member increases the thermal impedance between the melt surface and the interior of the MBE system to reduce the flux transient and increases the uniformity of the molecular beam over the area being processed, and over the time that the process is being conducted.

FIG. 3 shows a prior art design making use of a truncated conical crucible insert 31 with open top and bottom circular orifices inserted in a cylindrical crucible 30 which holds the liquid metal source 36. A radiant resistive heater element 34 is located in close proximity to the mouth of the cylindrical crucible and the truncated conical insert. The temperature of the cylindrical crucible is sensed and controlled by a thermocouple 35. The advantage of this cell configuration is that the surface area of the metal does not change from its initial surface area 32 to intermediate surface area 33 measured at a later time. Only when the edge of the metal surface touches the bottom edge of the cylindrical crucible will the surface area of the metal 37 decrease. This configuration significantly lessens the reduction in the evaporation rate as the metal is depleted in the crucible since the surface area of the metal stays approximately the same for a long period of time during metal evaporation. However this metal evaporator still has several problems. Since the source-to-substrate distance still increases with time, this will result in a reduction in metal evaporation rate. Therefore the crucible temperature still must be gradually increased with time in order to maintain a constant metal evaporation rate. Also this configuration leads to some focusing of the metal beam flux over the substrate as the metal surface recedes in the cylindrical crucible which adversely affects the deposition uniformity across the substrate. Another problem with this cell configuration is that the truncated conical crucible 31 is indirectly heated by the radiant heater element 34 through the walls of the cylindrical crucible 30. This leads to condensation of metal droplets on the conical crucible that fall back by gravity into the metal evaporator which leads to numerous “spitting” defects in the grown layers. This problem has been solved in another design that uses a self-heated truncated conical insert placed in a similar cell configuration. The source includes an open-ended crucible and a removable orificed covered plate for covering the open end of the crucible, with the cover plate having an encapsulated heater to reduce orifice blockage. The self-heated conical insert can be maintained at a higher temperature than the metal surface to eliminate any condensation of metal droplets on the insert.

Another evaporator configuration that behaves similarly to the previously described evaporator is illustrated in FIG. 4. In this design a single-piece crucible 40 is formed by chemical vapor deposition of pyrolytic Boron Nitride (PBN) on a shaped graphite mandrel. Through high temperature oxidation, the graphite mandrel is burned away leaving a cylindrically shaped PBN bottom reservoir 45 that contains the liquid metal source. A conical shaped nosecone 41 formed on top of this reservoir is used to broadly diffuse the metal beam flux to improve the uniformity of the deposited metal films. This evaporator design has several advantages over the previous designs. The single-piece crucible design eliminates any possibility of metal flux leakage since there are no mating surfaces between the reservoir and the nosecone. Also the nosecone can be heated to very high temperatures by the radiant heater element 44 to prevent condensation of metal droplets that can cause “spitting” defects. Additionally, the initial surface area remains constant throughout most of the lifetime of the metal source 46 until the edge of the metal surface 47 touches the crucible bottom 411. Since the source-to-substrate distance still increases with time, the cell temperature controlled by the thermocouple must still be gradually increased in order to maintain a constant metal evaporation rate. The deposited metal uniformity across the substrate will also degrade with time due to the focusing affect of the nosecone as the metal surface recedes in the cylindrical crucible due to metal depletion from evaporation. Another problem of the single piece crucible design is that the narrow opening of the nosecone attached to the reservoir requires loading of small solid pellets of the metal source material thus reducing the loading volume of the source material by approximately 50%.

The crucible 40 generally comprises a base section 45 and a conical section with a first or outer orifice 49 disposed at one end of the conical section and open to the exterior of the crucible 40. The base section 45 and a conical section form a single, unitary piece. The crucible 40 is formed of an inert, corrosion resistant material. A preferred material is PBN, such as PyroSyl™ sold by CVD Products, Inc. of Hudson, N.H. The crucible 40 is constructed via a chemical vapor deposition process set forth in detail below. All boundary edges between the base member 45 and conical member elements mentioned below in detail are preferably radius edges. In the embodiment of crucible 40 shown, the length and other dimensions of may be varied consistent with the basic teachings of this invention.

The base section 45 has a substantially cylindrical configuration with a side wall 416, a bottom 411 disposed at one end of the side wall, and a negative draft tapered wall or neck (formed in conjunction with nosecone 41) disposed at the opposite end of the side wall. The side wall 416 has a predetermined substantially uniform circumference and a predetermined length. The negative draft wall tapers inwardly (laterally) towards the central longitudinal axis (not shown) of the crucible 40 (and hence, the side wall 416) preferably at an angle approximately 45.0 degrees with respect to the longitudinal plane of the exterior of the base section 45. The negative draft wall terminates at its outward end to define a second or inner orifice 413. The second orifice 413 is a region of smallest diameter in the crucible 40.

The conical section is defined by the portion of the crucible extending from the second orifice 413 to the periphery of the first orifice 49. The conical section comprises a positive draft wall 414 and an annular lip 415. The wall 414 tapers outwardly (laterally) away from the central longitudinal axis of the crucible 40 at a preferred approximate angle of 9.0 degrees measured with respect to the central axis. The annular lip 415 extends outwardly from the terminal edge of the wall 414.

The crucible 40 is typically oriented upwardly at an angle for MBE. An element or compound is added to the crucible and heated by the dual filament system, for example, of an effusion source to form a melt. In use, the conical section of the crucible 40 yields a level of thickness uniformity which matches that provided by conical crucibles. Additionally though, the design minimizes depletion effects. In all types of cells the beam equivalent pressure at a constant cell temperature decreases over time due to depletion of the source melt material. This effect is greater in cells using conical crucibles because of more rapid reductions in melt surface area in those cells. The effect is further increased in hot lip cells because they are typically somewhat less efficient in their use of material. Presumably, this is due to reevaporation from the hot lip area, such reevaporation not being directed toward the substrate. The crucible 40 of this invention virtually eliminates depletion effect by providing a melt surface 42 which is consistent in size (area) and shape at different levels 43. The portion of the melt surface “seen” by the substrate is equivalent to the size of the inner orifice 413. In contrast, in crucibles which are conical throughout, the distance between the crucible orifice and the melt surface increases and the melt surface area decreases as the melt charge depletes in volume, thus causing them to exhibit enhanced depletion effects. Another advantage of the crucible 40 of this invention is the large crucible volume provided by the straight wall, cylindrical base section 45, which increases useful capacity in comparison to conical crucibles. A further advantage is that the inner orifice 413 provided by the integral conical section forms a thermal baffle between melt and the shutter (not shown) improving hydrodynamic stability and reducing shutter-related transients. Finally, the integrally formed conical section enables optimal positioning of the tip filament of the dual filament heating system to minimize oval defect production.

In another example, a phosphorus effusion source describes a sublimating and cracking apparatus for producing a beam of molecules to be deposited on a substrate. This example is particularly useful with phosphorus as the source material includes a vacuum jacket enclosing and supporting a red phosphorus crucible, a condensing crucible for white phosphorus and a connecting tube within a vacuum space. Red phosphorus is first transformed and deposited as white phosphorus in the condensing chamber, which is then directed to a cracking section where the white phosphorus is cracked and subsequently directed to the substrate.

Another example is an apparatus for varying the flux of a molecular beam emanating from an effusion source. The apparatus includes a means for controllably adjusting the angular distribution of a molecular field effusing from a source material within the effusion cell, thereby adjusting the flux of the beam. Also disclosed is a method which includes the step of selectively altering the angular distribution of an effusing molecular field produced by a heated source material, which comprises the molecular beam, thereby varying the flux of the beam.

Yet another example of an effusion source for the generation of molecular beams is adapted to be positioned at an angle to the horizontal within a vacuum chamber of an MBE system including heating structures around the source to create uniform temperatures across the source in planes substantially parallel to the horizontal. This causes uniform temperatures in planes substantially parallel to the horizontal in materials placed within the source and intended for MBE applications.

Another example comprises a vaporization chamber containing the material to be vaporized and provided with at least one opening with a given cross-section for maintaining the material to be vaporized in the liquid state within said chamber and for emitting controlled flow molecular beams. It further comprises a sleeve integral with the vaporization chamber surrounding the opening or openings having a given cross-section, and heating means for maintaining the temperature within the vaporization chamber and for obtaining an adequate temperature in the sleeve to prevent condensation of the vaporized material in said sleeve and in the opening or openings having a given cross-section.

Another example of an evaporation source incorporates a shaped nozzle. The evaporation source is such that an evaporation material is vaporized and jetted through a nozzle having a gradually opening cross-section, whereby the size of atom clusters of the jetted vapor can be controlled.

Another apparatus is a rapid response evaporator for material deposition in vapor and comprises a vessel which is heated to a temperature just above the melting temperature of the liquid which it contains. A funnel shaped evaporator structure is inserted into the heated liquid in which the vertical tube is a capillary structure to raise the heated liquid from the vessel. Because of the low thermal mass of the upper portion of the evaporator and the liquid in its capillary structure, it can respond to heat changes quickly enough to rapidly vary the rate of evaporation and the thickness of the deposited coating.

There are numerous problems and disadvantages associated with the prior art liquid metal evaporation sources discussed above. For example, these prior art embodiments suffer from inconsistent evaporation and deposition rates, melt depletion, exhibit a need for frequent recalibration to accompany associated changes in MBE process rates, and small, low capacity crucibles that result in a low overall throughput of substrate deposition.

### SUMMARY OF THE INVENTION

The present invention provides a new liquid metal evaporation source configuration, which overcomes the disadvantages and limitations of the prior art sources. More particularly, disclosed is a new liquid metal evaporation source for use in MBE and other related metal vacuum deposition techniques, which consists, in the preferred embodiment, of three separately heated temperature zones. The first zone is the evaporator, including an integral level sensor used to measure and regulate metal height, maintained at a high temperature to evaporate a liquid metal contained in a crucible. The second zone operates as a reservoir for the liquid metal source in the shape of a hollow cylinder with a close fitting circular piston, held at a temperature substantially below that of the evaporator but above the melting point of the metal. The third zone consists of a hollow transport tube that connects the evaporator and reservoir, sustained at an intermediate temperature between their temperature zones. When pressure is applied to the reservoir piston, liquid metal is forced through the tube into the evaporator.

Melt depletion due to metal evaporation and the consequent reduction in the metal deposition rate is a problem that is overcome by the subject invention. This is accomplished through the use of a separate high capacity reservoir to contain the liquid metal that is attached to the metal evaporator by means of a co-joining hollow transport tube. The reservoir is used to replenish the metal lost during the evaporation process. The reservoir is most conveniently formed in the shapes of a hollow cylinder with a close-mating circular piston made from refractory material, preferably high purity, densified graphite and/or pyrolytic boron nitride. The cylinder and piston can be machined to close tolerances to prevent leakage of the liquid metal out of the containing wall of the reservoir. The surface tension of the liquid metal prevents it from penetrating through the narrow gap between the reservoir cylinder and the circular piston walls. Linear motion of the piston in the cylinder is used to force the liquid metal through the hollow transport tube into the high temperature evaporator. The evaporator, hollow transport tube, and reservoir are all independently heated to prevent solidification of the liquid metal.

The height of the liquid metal in the evaporator can be easily sensed through the use of one or two conducting probes insulated from the evaporator crucible and are preferably made from graphite or other refractory materials that do not react with the heated liquid metal. A low resistance contact is formed when the liquid metal just comes in contact with the conducting probes similar to a liquid mercury switch that is normally used in thermostats to control ambient temperature. The low resistance contact between the metal and the conducting probes can be input into a feedback control circuit that can adjust the linear position of the piston in the reservoir by means of a motor-driven linear feedthrough attached to the piston. In this manner, a constant liquid metal height in the evaporator can be maintained to produce a constant evaporation rate on the substrate throughout the lifetime of the liquid metal source charge. In one embodiment of this invention, the evaporator, hollow transport tube, and reservoir cylinder are machined concentrically from a single piece of refractory material, preferably high purity, densified graphite on which may be applied a thin coating of pyrolytic graphite (PG) and/or pyrolytic boron nitride (PBN). This single-piece construction eliminates any possibility of liquid metal leakage between the evaporator, hollow transport tube, and the liquid metal reservoir.

In a second embodiment of this invention, both the concentric evaporator and the hollow transport tube are joined to the liquid metal reservoir by machined mating flanges. One version of this design joins the axes of the hollow transport tube and the reservoir at a right angle. This configuration allows the liquid metal reservoir to be located outside of the cell port on the MBE system or vacuum chamber. This enables a very large capacity reservoir to be constructed that provides very long operating times before the reservoir needs to be reloaded. This configuration also reduces the hydrostatic pressure on the piston in the reservoir from the total height of the liquid metal above the reservoir. The non-concentric configuration reduces the possibility of liquid metal leakage around the cylinder walls and piston by reducing the hydrostatic pressure of the liquid metal on the piston. This also enables much larger capacity reservoirs to be constructed that are external to the MBE vacuum chamber, which results in higher throughput of deposited substrates.

Consequently, it is an object of the invention to provide a new liquid metal evaporation source which comprises three separately heated temperature zones to minimize the melt depletion of the liquid metal and consequently minimize reduction in the deposition rates.

It is another object of this invention to provide a liquid metal evaporation source with an integral level sensor and an external reservoir for liquid metal to replenish the evaporator which results in a time invariant constant melt surface area and metal source-to-substrate distance. The two insulated conductor probes within the evaporator crucible comprise a sensor used to regulate the height of liquid metal. Feedback input from the sensor allows for active position adjustment of the reservoir piston. This level sensor feedback control enables a constant level height of the liquid metal in the evaporation source. This combination of height detection sensing and corresponding piston adaptation results in metal deposition rates which are time invariant.

A further object of this invention is to provide a constant evaporation rate and high uniformity of metal deposition on a rotating substrate or multiple substrate containing platen that is maintained throughout the entire capacity and operating time of the liquid metal reservoir source. The existence of a separate reservoir allows for the constant replenishment of metal lost during the evaporation process. A uniform evaporator liquid metal height is successfully maintained by the evaporator sensor/reservoir piston combination. As a result, a consistent evaporation area is preserved and a constant metal evaporation rate retained.

Yet another object of this invention is the elimination of the time-consuming process for re-calibration of the metal evaporation rates normally required in prior art conical crucible metal evaporation sources due to metal source depletion effects. As previously explained, a uniform evaporation area and rate is sustained within the evaporator through the implementation of a liquid metal height sensor that serves to adjust the reservoir piston's position. The provision for a separate reservoir connected to the evaporator by a hollow transport tube allows for large capacity reservoir construction. The metal source therefore is depleted at a much slower rate and re-calibration is not frequently required.

Still another object of this invention is to provide higher throughput of deposited substrates in an MBE system. A non-concentric system configuration allows reservoir location outside of the vacuum chamber of the MBE system. This provides an opportunity for a large capacity reservoir to be utilized, allowing for longer operation periods and a resulting increased throughput.

Other objects, features, and characteristics of the present invention, as well as the methods of operation and functions of the related elements of the structure, and the combination of parts and economies of manufacture, will become more apparent upon consideration of the following detailed description with reference to the accompanying drawings, all of which form a part of this specification.

### BRIEF DESCRIPTION OF THE DRAWINGS

A further understanding of the present invention can be obtained by reference to a preferred embodiment set forth in the illustrations of the accompanying drawings. Although the illustrated embodiment is merely exemplary of systems for carrying out the present invention, both the organization and method of operation of the invention, in general, together with further objectives and advantages thereof, may be more easily understood by reference to the drawings and the following description. The drawings are not intended to limit the scope of this invention, which is set forth with particularity in the claims as appended or as subsequently amended, but merely to clarify and exemplify the invention.

For a more complete understanding of the present invention, reference is now made to the following drawings in which:

FIG. 1 shows a cross-sectional view of a prior art conical crucible, liquid metal evaporator, and heated substrate in an MBE system;

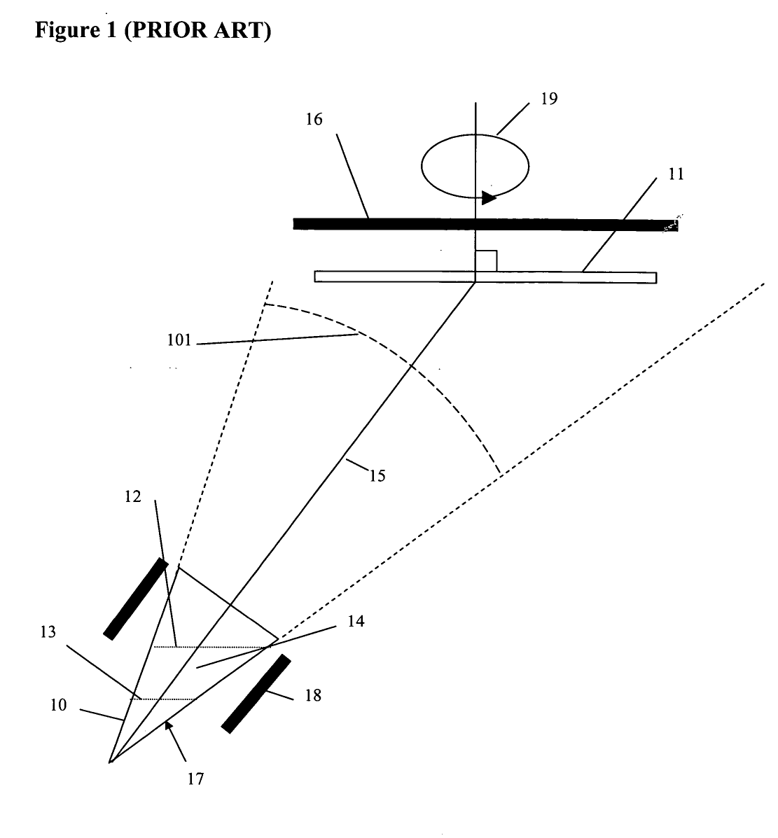

FIG. 2 illustrates the change in liquid metal surface area with time due to metal depletion from evaporation in a prior art inclined conical crucible, such as that shown in FIG. 1;

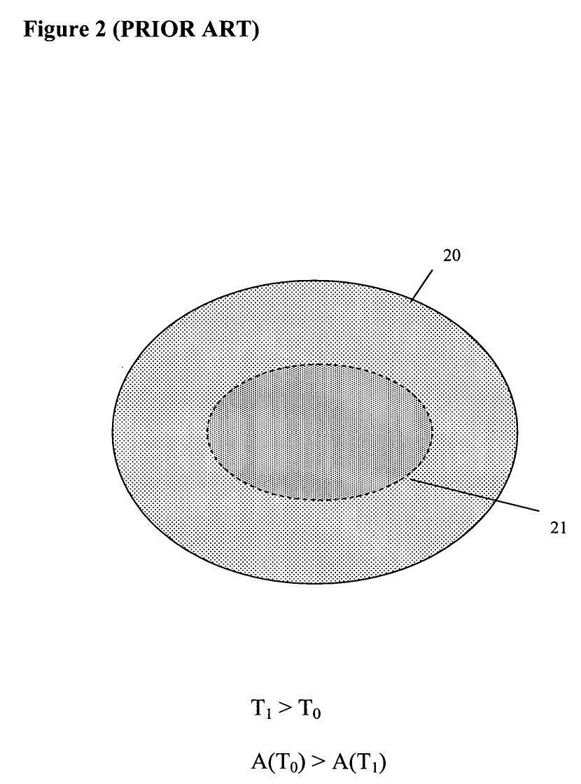

FIG. 3 shows a cross-sectional view of a prior art truncated crucible insert in a cylindrical crucible containing a liquid metal;

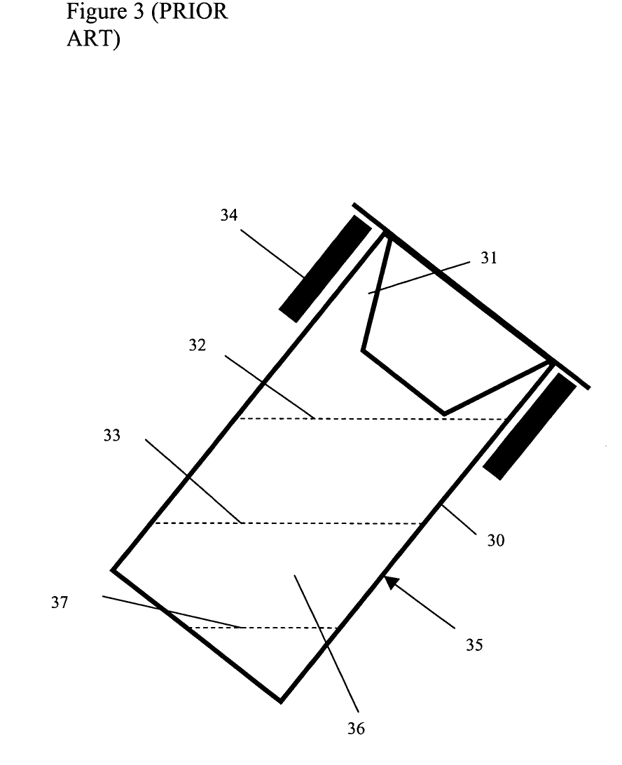

FIG. 4 shows a front view of a prior art unibody, monolithic negative draft MBE crucible;

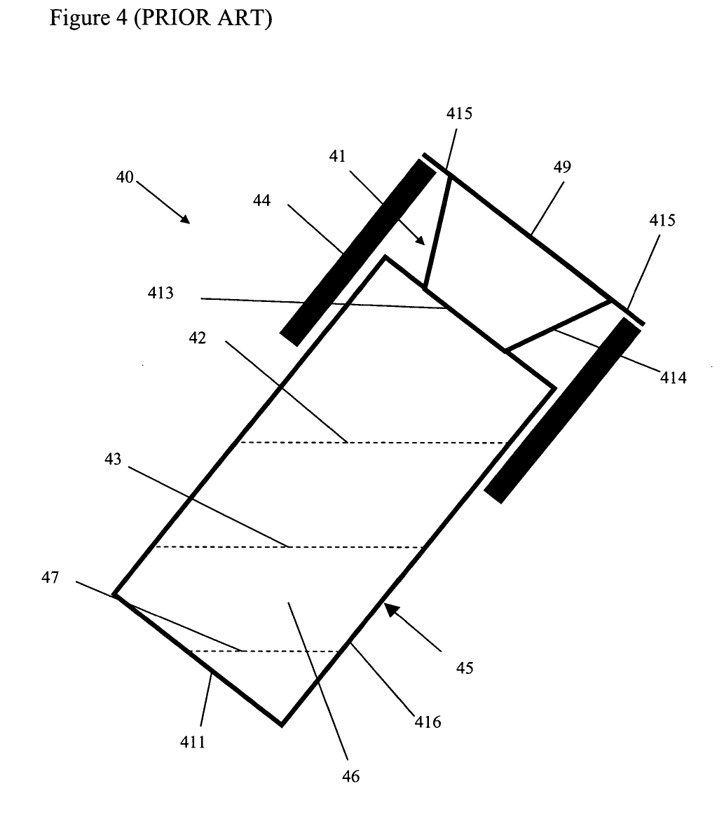

FIG. 5 shows a cross-sectional view of one embodiment of a liquid metal evaporation source according to the present invention illustrating a single-piece concentric evaporator crucible, hollow transport tube and liquid metal reservoir wherein the liquid metal reservoir consists of a hollow cylinder and mating piston machined from a single piece of refractory material together with an integral liquid metal level sensor;

FIG. 6 shows a cross-sectional view of a preferred embodiment of a liquid metal evaporation source according to the present invention illustrating a concentric evaporator and hollow transport tube joined by leak-proof mating flanges at a right angle to an external cylindrical reservoir and mating piston;

FIGS. 7A & 7B show a schematic diagram of the preferred embodiment of an integral liquid metal level sensor according to the present invention comprising a PBN coated graphite nosecone with an extended sensor probe that is insulated from the graphite crucible wall and is inserted in the top opening of the evaporator crucible; and

FIG. 8 shows a schematic diagram of the preferred embodiment of an automated feedback sensor control circuit according to the present invention to control the linear position of the piston within the evaporator to maintain a constant liquid metal level.

### DESCRIPTION OF THE PREFERRED EMBODIMENTS

As required, a detailed illustrative embodiment of the present invention is disclosed herein. However, techniques, systems and operating structures in accordance with the present invention may be embodied in a wide variety of forms and modes, some of which may be quite different from those in the disclosed embodiment. Consequently, the specific structural and functional details disclosed herein are merely representative, yet in that regard, they are deemed to afford the best embodiment for purposes of disclosure and to provide a basis for the claims herein which define the scope of the present invention. It should be noted that those individuals skilled in the art may be able to make some modifications of the preferred embodiments but which are based upon the underlying teachings contained within the subject invention.

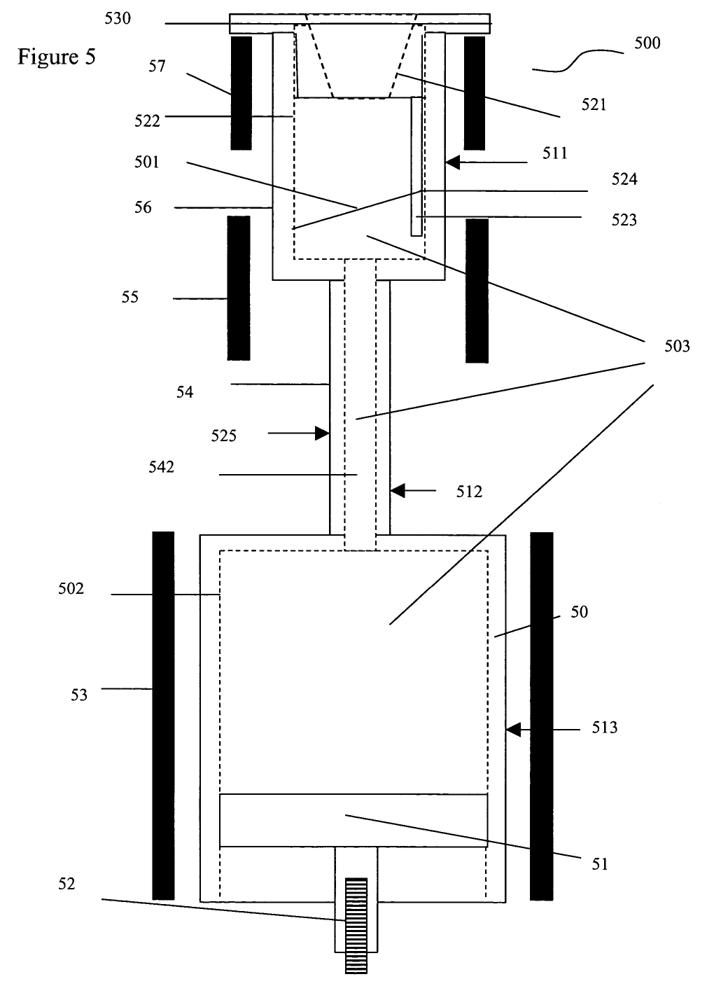

Referring first to FIG. 5, illustrated is one embodiment of a liquid metal evaporation source 500 according to the subject invention. Specifically, liquid metal evaporator 56, hollow transport tube 54, and hollow reservoir cylinder 50 are all machined from a single piece of refractory material, preferably high-purity densified graphite that is optionally coated with a thin layer of chemical vapor deposited pyrolytic graphite (PG) or pyrolytic boron nitride (PBN). Likewise, a close-mating piston cylinder 51 is machined from the same or similar refractory material to make a leak-tight seal for the liquid metal 503 held in the reservoir cylinder 50. The evaporator wall 522, the hollow transport tube wall 542, and the hollow reservoir wall 502 which contain the liquid metal 503 are preferably machined in cylindrical form to minimize the gaps between the reservoir piston 51 and optional nosecone and level sensor 521. The liquid metal will be contained within the reservoir cylinder by the surface tension of the liquid metal under certain conditions wherein the gap separating the walls of the reservoir cylinder 502 and the piston 51 are machined to be within required tolerances. A mathematical expression for the maximum permissible gap spacing between the cylindrical walls of the reservoir and piston is derived in subsequent paragraphs.

Evaporator heater element 57, hollow transport tube heater element 55, and reservoir heater element 53 are used to respectively heat by infrared radiation the walls of the evaporator 56, hollow transport tube 54, and reservoir 50 to prevent solidification of the liquid metal in any part of cell 500. Graphite has efficient black-body radiation absorption that will reduce the required heater element powers to achieve nominal operating temperatures for the cell in comparison to other refractory materials such as pyrolytic boron nitride (PBN) or SiO₂ (quartz). Evaporator thermocouple 511, hollow transport tube thermocouple 512, and reservoir thermocouple 513 are used to independently sense and control the respective temperatures in the three separate temperature zones. Also optional radiation shields typically made from Tantalum (Ta) foil (not shown) and optional water-cooling jacket (not shown) to surround the heater elements and provide thermal isolation of the respective temperature zones may be used in accordance with the invention. Under normal operation, evaporator 56 is preferably held at the highest temperature to vaporize the liquid metal, while hollow transport tube 54 is held at some intermediate temperature and reservoir 50 is held at the lowest temperature, preferably just slightly above the melting point of the metal material being used for deposition. Of course, other temperature arrangements may be used, such as maintaining each of evaporator 56, hollow transport tube 54 and reservoir 50 at the same temperature.

Liquid metal 503 can be forced by the piston 51 into the evaporator 56 by means of an attached linear motion shaft 52. The position of the linear motion shaft 52 can be changed either manually or optionally through an attached motor drive. By this means, liquid metal can be forced into the evaporator to replace liquid metal that is depleted through the metal evaporation process. The introduction of an optional level sensor 523 can be used to sense and regulate the position of the liquid metal surface 501 therein to maintain a constant metal evaporation rate at a fixed evaporator temperature sensed and controlled by the evaporator thermocouple 511.

An optional conical nosecone with attached level sensor 521 can be inserted within the evaporator cylinder wall 522. The conical nosecone section is used to provide dispersion of the evaporated metal flux to obtain uniform thickness deposition of the metal on the coated substrates. The angle of the nosecone is designed to simultaneously achieve optimum deposited metal thickness uniformity on the coated substrates together with low consumption of the liquid metal in the evaporation process. A leak-tight seal can be made using mating flat flanges 530 between the lip of the conical nosecone with attached level sensor 521 and the top lip of the evaporator crucible 56.

In the preferred embodiment, the conical nosecone with attached level sensor 521 is preferably machined from a single piece of high purity graphite which is coated with a thin insulating layer of pyrolytic boron nitride (PBN). An electrically conducting level sensor contact point 524 is made by machining away a small area of the PBN coating on the graphite level sensor probe 523. An electrical contact to the graphite nosecone and level sensor (not shown) can be made with an insulated threaded metal rod preferably made from refractory metal such as Molybdenum (Mo), Tantalum (Ta), or Tungsten (W) that attaches to a machined threaded hole through the PBN insulating layer into the conducting graphite of the nosecone with attached level sensor 521. A second electrical contact can be made to the liquid metal 503 by means of a separate electrical wire contact 525 to the electrically conducting graphite wall of the cell body 500. The electrical resistance between the level sensor probe contact point 524 and the liquid metal contact point on the cell body 525 is determined by the vertical height of the liquid metal 501 contained in the evaporator 56. When the vertical height of the liquid metal 501 is below the level sensor contact point 524, the electrical resistance between the probes is very high (open circuit). When the vertical height of the liquid metal 501 is equal to or above the level sensor contact point 524, the electrical resistance between the probes is very low (short circuit). This liquid metal electrical contact switch is similar to that of a Mercury (Hg) switch used in thermostats that are used to control heating and cooling systems to regulate ambient room temperature. In a similar manner, the level sensor can be used to sense and control the position of the piston 51 by means of a linear actuator 52 to maintain a constant liquid metal height in the evaporator to maintain a constant metal evaporation rate at a fixed evaporator temperature. The use of the two level sensor probes to automatically control the liquid metal height in the evaporator by means of motor drive of the piston linear actuator is described in subsequent paragraphs.

Proper operation of the liquid metal evaporation source of the subject invention requires that the liquid metal is contained within the reservoir and does not leak past the piston. The diameter of the reservoir inner cylinder wall 502 must be slightly larger than the outer diameter of the cylindrical piston 51 to form a sliding leak-tight seal between these parts. For the case of a liquid metal that does not wet or react with the graphite reservoir cylinder 502 and the cylindrical piston 51, containment of the liquid metal within the reservoir relies upon the surface tension of the liquid metal. Under certain design conditions, the liquid metal is prevented from flowing past the small gap separating the reservoir inner cylinder walls and the piston cylinder walls.

A quantitative expression is derived which relates the maximum permissible gap between the reservoir cylinder inner diameter and piston cylinder outer diameter to insure containment of the liquid metal within the reservoir by the surface tension of the liquid metal. Work must be done on the closed system in order to change the surface area of the liquid metal when it is forced into the gap between the reservoir cylinder and piston. The differential work required to increase the liquid metal surface area is given by

$$\begin{matrix}ⅆ {G}_{surface} = γ ⅆ A & ( Equation 2 ) \\ = γ [ π D + π ( D + Δ ) ] ⅆ h \sim 2 γπ D ⅆ h & ( Equation 3 )\end{matrix}$$

where dG_{surface} is the change in surface energy in the liquid metal, γ is the surface tension of the liquid metal, dA is the differential change in surface area of the liquid metal, D is the diameter of the piston, Δ is the small gap between the reservoir cylinder wall and piston cylinder wall, and dh is the differential vertical height change of the liquid metal within the gap Δ between the reservoir cylinder and piston cylinder.

The internal pressure of the liquid metal at the gap between the reservoir and piston results from hydrostatic pressure due to the vertical height difference of the liquid metal surface 501 above the piston 51 and is given by
P=ρgh (Equation 4)
where P is the hydrostatic pressure, ρ is the density of the liquid metal, g is the gravitational constant, and h is the vertical height difference between the liquid metal in the evaporator above the piston surface.

The work performed by the hydrostatic pressure of the liquid metal forcing the liquid metal within the piston gap is given by
dGₚᵣₑₛₛᵤᵣₑ=P[πDΔdh]=[ρgh][πDΔdh] (Equation 5)

Under equilibrium, the differential energies are the same. The threshold condition before the liquid metal will flow past the piston gap Δ is determined by setting Equations 3 and 5 to be equal and is given by
2γπDdh=[ρgh][πDΔdh] (Equation 6)

The maximum permissible gap Δ that can be used between the reservoir cylinder and piston walls can be determined from Equation 6 and is given by
Δ=2γ/[ρgh] (Equation 7)

Thus the maximum permissible gap Δ is given by the liquid metal surface tension multiplied by two and divided by the hydrostatic pressure of the liquid metal exerted upon the piston surface. The design gap between the reservoir and the piston is therefore chosen to be smaller than that given by Equation 7 to insure sufficient margin so that the liquid metal will never penetrate past the open space gap separating the piston outer cylinder wall from the reservoir inner cylinder wall. This relation also determines the maximum permissible wear between the graphite walls of the reservoir inner cylinder and piston outer cylinder before leakage of liquid metal will occur past the piston.

Example: Calculate the maximum permissible gap Δ required for a leak-tight seal between the reservoir inner cylinder and piston outer cylinder for Ga where the vertical height of the liquid metal in the evaporator is 30 cm above the piston. Substituting into Equation 7 gives

$$Δ = 2 ( 720 dynes \text{/} cm ) / \\ [ 5.9 gm \text{/} {cm}^{3} 980 cm \text{/} {s}^{2} 30 cm ] \\ = 0.0083 cm \qquad ( Equation 8 )$$

A machined sliding gap Δ=0.003-0.004 cm can be achieved between a reservoir inner cylinder and piston outer cylinder with nominal diameters of 10 cm using a so-called “sliding fit” between these parts. This machining tolerance provides a good design margin by a factor of 2 to obtain a leak-tight seal for Ga between the reservoir and piston using a vertical height of 30 cm for Ga in the evaporator above the piston. Experimental measurements performed on a model reservoir are also in excellent agreement with this calculation.

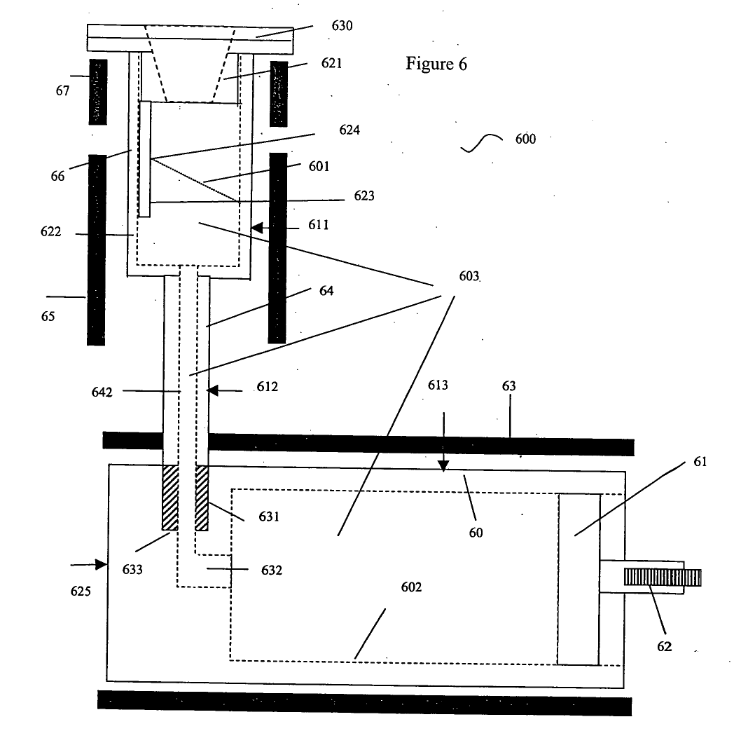

Turning next to FIG. 6 shown is the preferred embodiment of a liquid metal evaporation source 600 according to the subject invention. In this configuration, evaporator 66 and hollow transport tube 64 may be attached to the reservoir body 60 using threaded assemblies that are leak-tight to the liquid metal or by any other known leak-tight attachment means. Concentric evaporator 66 and attached hollow transport tube are joined at right angles to the axis of the reservoir cylinder 60 preferably by a threaded joint 631. Flat mating flanges 633 on the threaded end of the hollow transport tube 64 and threaded reservoir cylinder body 60 will insure a leak-tight seal. Liquid metal 603 will pass through the reservoir body into the hollow transport tube 64 by a co-joining right angle passageway 632 machined into the reservoir cylinder body.

During operation this preferred embodiment of the subject invention shown in FIG. 6 is similar to that of alternate embodiment shown in FIG. 5. That is, liquid metal evaporator 66, hollow transport tube 64, and hollow reservoir cylinder 60 are machined from a refractory material, preferably high-purity densified graphite that is optionally coated with a thin layer of chemical vapor deposited pyrolytic graphite (PG) or pyrolytic boron nitride (PBN). Likewise, a close-mating piston cylinder 61 is machined from the same or similar refractory material to make a leak-tight seal for the liquid metal 603 held in the reservoir cylinder 60. The evaporator wall 622, the hollow transport tube wall 642, and the hollow reservoir wall 602 which contain the liquid metal 603 are preferably machined in cylindrical form to minimize the gaps between the reservoir piston 61 and optional nosecone and level sensor 621. The liquid metal will be contained within the reservoir cylinder by the surface tension of the liquid metal under certain conditions wherein the gap separating the walls of the reservoir inner cylinder 602 and the piston outer cylinder 61 are machined to be within required tolerances as previously described.

Evaporator heater element 67, hollow transport tube heater element 65, and reservoir heater element 63 are respectively used to heat by infrared radiation the walls of evaporator 66, hollow transport tube 64, and reservoir 60 to prevent solidification of the liquid metal in any part of cell 600. Graphite has efficient black-body radiation absorption that will reduce the required heater element powers to achieve nominal operating temperatures for the cell in comparison to other refractory materials such as pyrolytic boron nitride (PBN) or SiO₂ (quartz). Evaporator thermocouple 611, hollow transport tube thermocouple 612, and reservoir thermocouple 613 are used to independently sense and control the respective temperatures in the three temperatures in the three separate temperature zones. Also optional radiation shields typically made from Tantalum (Ta) foil (not shown) and optional water-cooling jacket (not shown) to surround the heater elements and provide thermal isolation of the respective temperature zones may be used in accordance with the invention. Under normal operation, evaporator 66 is preferably held at the highest temperature to vaporize the liquid metal, while hollow transport tube 64 is held at some intermediate temperature and reservoir 60 is held at the lowest temperature, preferably just slightly above the melting point of the metal material being used for deposition. Of course, other temperature arrangements may be used, such as maintaining each of evaporator 66, hollow transport tube 64 and reservoir 60 at the same temperature.

Liquid metal 603 can be forced by the piston 61 into the evaporator 66 by means of an attached linear motion shaft 62. The position of the linear motion shaft 62 can be changed either manually or optionally through an attached motor drive. By this means, liquid metal can be forced into the evaporator to replace liquid metal that is depleted through the metal evaporation process. The introduction of an optional level sensor 623 can be used to sense and regulate the position of the liquid metal surface 601 therein maintaining a constant metal evaporation rate at a fixed evaporator temperature sensed and controlled by the evaporator thermocouple 611.

An optional combined conical nosecone with attached level sensor 621 can be inserted within the evaporator cylinder wall 622. The conical nosecone section is used to provide dispersion of the evaporated metal flux to obtain uniform thickness deposition of the metal on the coated substrates. The angle of the nosecone is designed to simultaneously achieve optimum deposited metal thickness uniformity together with low consumption of the liquid metal in the evaporation process. A leak-tight seal can be made using mating flat lip flanges 630 between the conical nosecone with attached level sensor 621 and the top lip of the evaporator crucible 66.

In the preferred embodiment, the conical nosecone with attached level sensor 621 is preferably machined from a single piece of high purity graphite which is coated with a thin insulating layer of pyrolytic boron nitride (PBN). An electrically conducting level sensor contact point 624 is made by machining away a small area of the PBN coating on the graphite level sensor probe 623. An electrical contact to the graphite nosecone and level sensor (not shown) can be made with an insulated threaded metal rod preferably made from refractory metal such as Molybdenum (Mo), Tantalum (Ta), or Tungsten (W) that attaches to a machined threaded hole through the PBN insulation into the conducting graphite. A second electrical contact can be made to the liquid metal 603 by means of a separate electrical wire contact 625 to the electrically conducting graphite wall of the cell body 600. The electrical resistance between the level sensor probe contact point 624 and the liquid metal contact point 625 is determined by the vertical height of the liquid metal 601 contained in the evaporator 66. When the vertical height of the liquid metal is below the level sensor contract point 624, the electrical resistance between the probes is very high (open circuit). When the vertical height of the liquid metal 601 is equal to or above the level sensor probe, the electrical resistance between the probes is very low (short circuit). This liquid metal electrical contact is similar to that of a Mercury (Hg) switch used in thermostats that are used to control heating and cooling systems to regulate ambient room temperature. In a similar manner the level sensor can be used to sense and control the position of the piston 61 by means of a linear actuator 62 to maintain a constant liquid metal height in the evaporator to maintain a constant metal evaporation rate at a fixed evaporator temperature. The use of the level sensor to automatically control the liquid metal height in the evaporator by means of motor drive of the piston linear actuator is described in subsequent paragraphs.

An advantage of this cell configuration is clearly shown in FIG. 6. Specifically, the large capacity of external reservoir 60 for liquid metal 603 may be made independently as large as practical since reservoir 60 may be placed outside the source flanges of the MBE or vacuum deposition system. This enables the system to be loaded with a very large supply of liquid metal 603 to allow continuous operation of the MBE system for a very long period (e.g. one year or more). In addition, liquid metal 603 may be lowered back into reservoir 60 prior to venting the vacuum system to atmospheric pressure before, for example, periodic MBE maintenance thus preventing extensive oxidation of the metal source.

Another important benefit of the right angle evaporator/reservoir design is that it reduces the maximum hydrostatic pressure of the liquid metal exerted upon the piston as given by the expression in Equation 7. This is because the piston is positioned above the lowest point of the liquid metal contained in the reservoir cylinder walls 602. In contrast, the full hydrostatic pressure of the liquid metal is exerted on the piston in the fully concentric cell design shown in FIG. 5 since the piston is at the lowest vertical point in this configuration. Thus the right angle reservoir design increases the permissible gap tolerance requirement between the reservoir cylinder walls 602 and the piston cylinder walls 61 which enables very large capacity liquid metal reservoirs to be constructed. In addition, the maximum force exerted on the piston 61 and piston linear actuator 62 is also reduced. This will reduce the force requirement ratings on the linear actuator and motor drive required for automatic control of the piston position.

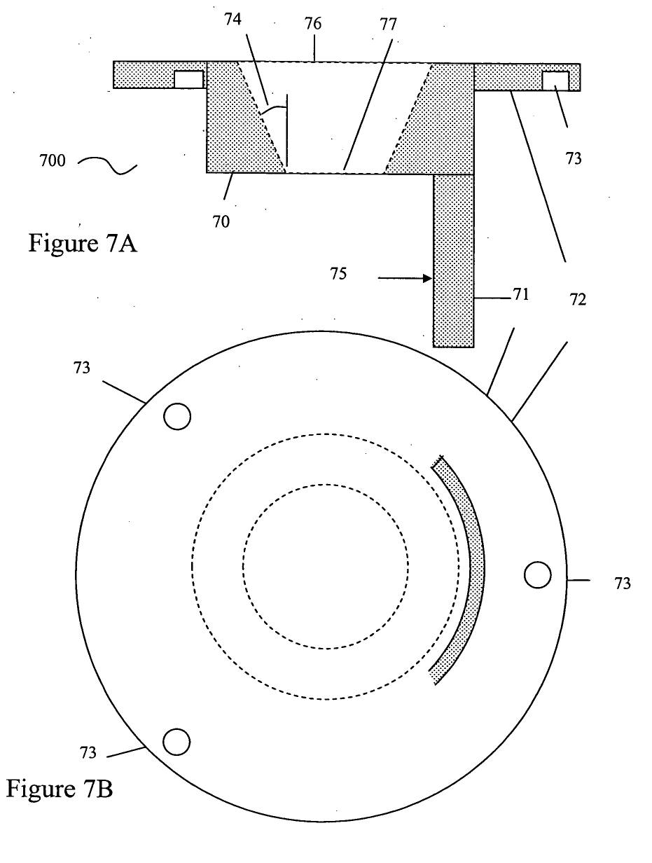

Referring next to FIG. 7A, shown is an enlarged schematic of the preferred embodiment of the nosecone cap with an attached liquid metal level sensor probe 700 according to the present invention. A cross-section of the conical nosecone with attached level sensor probe 70 is shown in FIG. 7A. This part is preferably made from electrically and thermally conductive graphite and is coated with preferably a thin pyrolytic boron nitride (PBN) layer for insulation of the nosecone with attached level sensor probe from the graphite evaporator sidewalls 522 (FIG. 5) or 622 (FIG. 6). The coefficient of thermal expansion of the graphite is chosen to be similar to PBN to prevent cracking or delamination of this insulating layer from the nosecone with attached level sensor probe. The conical orifices in the nosecone with outer diameter 76 and inner diameter 77 and angular taper 74 is used to provide dispersion of the metal evaporation to achieve desired uniformity of metal deposition over the coated substrates. The conical orifice diameters and taper angle are also chosen to achieve efficient utilization of the liquid metal in the metal evaporation process. The level sensor probe 71 is attached to the bottom of the nosecone part and is inserted into the liquid metal contained within the evaporator. An electrical contact point 75 to the liquid metal is formed by machining away a small area of the PBN insulating layer covering the graphite. Electrical contact to the sensor probe is provided by a machined threaded hole 73 that is attached to an insulated refractory metal rod (not shown) made from Molybdenum (Mo), Tantalum (Ta), or Tungsten (W). A flat lip flange 72 is used to seal the nosecone to a mating flat lip flange on the evaporator crucible. This prevents any evaporation of the liquid metal through these flanges which is problematic if the metal comes in contact with the Ta top filament heaters 57 (FIG. 5) or 67 (FIG. 6) which can cause the filament heaters to burn out prematurely. The two flat flanges are joined together using insulated threaded rods or screws (not shown) which attach to the threaded holes 73 to provide a leak-tight seal.

A plan view of the nosecone and level sensor is shown in FIG. 7B. It is seen that the extended level sensor probe is preferably formed in the shape of a partial annular ring or crescent which inserts into the liquid metal in the evaporator. The outer radius of the level sensor probe is machined to form a close fit with the inner cylinder walls of the evaporator crucible. This will improve radiant heat transfer to the level sensor probe due to its close proximity with the evaporator crucible sidewall in order to prevent condensation of liquid metal droplets on the level sensor probe. Metal droplets that condense on the level sensor probe can be a source of defects in the deposited metal films on the coated substrates. A thin arc is machined through the insulating PBN layer at a fixed distance below the nosecone bottom orifice 77 to provide the contact point 75 for the level sensor probe. This machined thin arc contact point will provide the same relative liquid metal contact point with respect to the top of the evaporator even if the nosecone is rotated slightly (e.g. within 60°) from its nominally intended installation position. This will insure reproducible positioning of the liquid metal height in different cells to produce similar metal evaporation characteristics. It is preferable to locate the level sensor point below the bottom nosecone orifice so that the nosecone can be maintained at a higher temperature compared to the liquid metal that is evaporated. This will prevent condensation of small metal droplets on the nosecone that can fall back into the liquid metal which can cause defects in the deposited metal films. This metal droplet formation is the origin of so-called “oval defects” that are found in the growth of GaAs by MBE and must be avoided. The level sensor contact position 75 can also be adjusted to reduce the volume of liquid metal contained within the evaporator crucible. Smaller volume capacity of liquid metal within the evaporator crucible will enable faster thermal response of the evaporator to effect changes in the metal evaporation rates if desired. Preferably, three threaded holes 73 are formed in the bottom of the flat sealing lip flange on the nosecone. Insulated threaded rods or screws made from refractory metal (not shown) are used to join together the lip flange to the flat lip flange on the top of the evaporator crucible to provide a leak-tight seal.

The height of the liquid metal within the evaporator crucible can be determined by use of the level sensor probe. One electrical contact to the liquid metal is made by contact of a conducting wire 525 (FIG. 5) or 625 (FIG. 6) to the electrically conductive graphite cell body containing the liquid metal. When the vertical height of the liquid metal is below the contact point 75 on the level sensor, the resistance between the two probes will be very high (open circuit). Therefore under the open circuit condition, it is known that the liquid metal is below the desired height in the evaporator crucible. Conversely, when the vertical height of the liquid metal is equal to or above the level sensor contact point 75, the resistance between the two probes is very low (short circuit). Thus by moving the piston in the reservoir up and down slightly, the liquid metal height can be very accurately set to exactly the height of the contact point 75 on the level sensor probe. By this means, very reproducible metal evaporation rates can be maintained at a fixed evaporator temperature over the life of the charge of liquid metal contained within the evaporator. The piston position can be set either manually by measuring the resistance between the two probes or automatically using a simple motor control circuit as described in the next paragraphs.

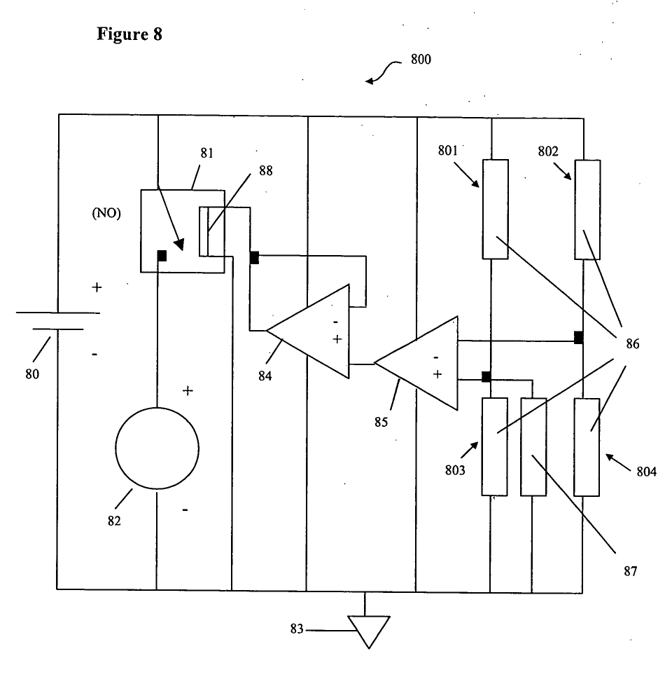

Turning now to FIG. 8, shown is a schematic diagram of a simple motor control circuit 800 which may be used in accordance with the present invention to control the motion of motor-driven linear feedthrough 52 or 62 and hence reservoir piston 51 or 61. Preferably, control circuit 800 uses an op amp comparator 85 and an op amp unity gain buffer amplifier 84 to drive a low voltage relay 81. DC motor 82 is connected to DC power supply 80 through the normally open (NO) switched contacts in relay 81, and is in turn used to drive a linear motion shaft, for example, linear feedthrough 52 or 62 shown in FIGS. 5 and 6, respectively, attached to reservoir piston 51 or 61. In addition, a bias network 86 of four resistors 801, 802, 803, 804, preferably with values of 100 Ω, 100 Ω, 10 Ω and 5 Ω, respectively, is used to set the threshold level of op amp comparator 85. When the liquid metal level sensor 87 is open circuit, the output of op amp comparator 85 is high thus energizing coil 88 in relay 81, which applies voltage to DC motor 82. Consequently, piston 51 or 61 will continue to push liquid metal 502 or 602 into evaporator 56 or 66 until the surface of the metal comes in contact with level sensor probes 524 or 624. Thus, when liquid metal 503 or 603 touches level sensor probes 524 or 624, a low resistance approximating a short circuit will develop that effectively forces the positive input of op amp comparator 85 to ground potential 83. In this case, the output of op amp comparator 85 is low thus turning off relay coil 88 and removing voltage from DC motor 82.

The operation of motor control circuit 800 will automatically regulate the height of liquid metal 503 or 603 so that it continuously remains in contact with level sensor probes 524 or 624. Also, a slight amount of hysteresis can be built into motor-driven linear feedthrough 52 or 62 (typically<1 mm) to prevent oscillations therein due to vibrations in the liquid melt surface. Also, not shown is a protection mechanism to prevent piston 51 or 61 from continuously moving into reservoir 50 or 60 in the case where the wire leads to liquid metal sensor probes 524 or 624 are broken, thereby resulting in an open circuit. For example, a mechanical stop can be used to limit travel of piston 51 or 61 over a short period of time. Alternatively, a safety mechanism could use an electronic detection circuit to periodical measure the sensor probe resistance. That is, if the sensor resistance remained high for too long of a time period, then DC voltage to the motor would be disabled and an alarm would be activated.

Alternatively, the output voltage from relay 81 can be used as an input control signal for a stepper motor controller. The height of the liquid metal in the evaporator 501 or 601 could be precisely lowered within the evaporator relative to the level sensor contact point 524 or 624. This could be used to effect reproducible reductions in metal evaporation rates by lowering the liquid metal height in the evaporator.

While the present invention has been described with reference to one or more preferred embodiments, such embodiments are merely exemplary and are not intended to be limiting or represent an exhaustive enumeration of all aspects of the invention. The scope of the invention, therefore, shall be defined solely by the following claims. Further, it will be apparent to those of skill in the art that numerous changes may be made in such details without departing from the spirit and the principles of the invention. It should be appreciated that the present invention is capable of being embodied in other forms without departing from its essential characteristics.

1. A liquid metal evaporation source for use in Molecular Beam Epitaxy (MBE) or vacuum deposition processes, said source comprising:
a high temperature evaporator;
an intermediate temperature hollow transport tube; and
a low temperature hollow reservoir cylinder with close-mating cylindrical piston;
wherein each of said evaporator, said transport tube and said reservoir cylinder include a radiant resistive heater element with a thermocouple to sense and regulate the heater power, and
wherein at least one conducting probe is used to sense contact with liquid metal in said evaporator by making a low resistance electrical contact in which the level of said conducting probe can be used to control a position of said piston in said reservoir cylinder via an automatic feedback control circuit which drives a motor attached to a linear motion vacuum feedthrough which in turn is attached to said piston and is used to regulate a constant height of said liquid metal in said evaporator to maintain a constant evaporation rate of said liquid metal from said evaporator at a fixed evaporator temperature.

2. An evaporation source according to claim 1, wherein at least one of said evaporator, said hollow transport tube, said reservoir, and said piston are machined from a refractory material.

3. An evaporation source according to claim 2, wherein said refractory material is densified graphite.

4. An evaporation source according to claim 2, wherein at least one of said evaporator, said reservoir cylinder, said transport tube and said piston are coated with a layer of Pyrolytic Graphite (PG).

5. An evaporation source according to claim 2, wherein at least one of said evaporator, said reservoir cylinder, said transport tube and said piston are coated with a layer of Pyrolytic Boron Nitride (PBN).

6. An evaporation source according to claim 2, wherein at least one of said evaporator, said reservoir cylinder, said transport tube and said piston are coated with a layer of Pyrolytic Silicon Carbide (PSiC).

7. An evaporation source according to claim 2, wherein at least one of said evaporator, said reservoir cylinder, said transport tube and said piston are coated with a layer of Pyrolytic Aluminum Nitride (PAN).

8. An evaporation source according to claim 2, wherein at least one of said evaporator, said hollow transport tube and said reservoir cylinder is machined from a single piece of refractory material in essentially a concentric configuration.

9. An evaporation source according to claim 1, wherein said evaporator and said hollow transport tube are joined at a right angle to the axis of said reservoir cylinder by leak-tight flat flanges.

10. An evaporation source according to claim 9, wherein said reservoir cylinder is joined to said hollow transport tube and said evaporator via a passageway for said liquid metal.

11. An evaporation source according to claim 9, wherein said leak-tight flat flanges are attached using threaded assemblies.

12. An evaporation source according to claim 9, wherein said leak-tight flat flanges are attached using refractory clamps.

13. An evaporation source according to claim 1, wherein said evaporator and said hollow transport tube are joined at an angle ranging between 0 to 180 degrees to said reservoir cylinder along its axis by leak-tight flanges.

14. An evaporation source according to claim 13, wherein said reservoir cylinder is joined to said hollow transport tube and said evaporator via a passageway for said liquid metal.

15. An evaporation source according to claim 13, wherein said leak-tight flat flanges are attached using refractory clamps.

16. An evaporation source according to claim 13, wherein said leak-tight flat flanges are attached using threaded assemblies.

17. An evaporation source according to claim 16, wherein said refractory clamps are joined together using refractory nuts and bolts preferably made from molybdenum.

18. An evaporation source according to claim 16, wherein said refractory clamps are joined together using refractory nuts and bolts preferably made from densified graphite.

19. An evaporation source according to claim 1, wherein said high temperature evaporator includes an evaporator nosecone.

20. An evaporation source according to claim 19, wherein said evaporator nosecone is of a shape suitable for providing a metal beam flux profile incident upon a substrate.

21. An evaporation source according to claim 1, wherein at least one of said conducting probes are made from a non-reacting refractory material.

22. An evaporation source according to claim 21, wherein said refractory material is densified graphite.

23. An evaporation source according to claim 22, wherein said conducting probes are insulated from each other and insulated from the walls of the evaporator.

24. An evaporation source according to claim 23, wherein said conducting probes are insulated from each other and insulated from the walls of the evaporator using non-conductive ceramic coating.

25. An evaporation source according to claim 23, wherein said ceramic coating is made from pyrolytic boron nitride (PBN).

26. An evaporation source according to claim 24, wherein at least one of said conducting probes is positioned above the surface of said liquid metal.

27. An evaporation source according to claim 24, wherein at least one of said conducting probes is inserted from below the surface of said liquid metal through said evaporator.

28. An evaporation source according to claim 21, wherein at least one of said conducting probes makes a first contact with said liquid metal on its surface and makes a second contact with said liquid metal through conductive walls of said evaporator.

29. An evaporation source according to claim 1, wherein said radiant resistive heater elements are made from refractory materials.

30. An evaporation source according to claim 29, wherein said refractory material is densified graphite.

31. An evaporation source according to claim 30, wherein said radiant resistive heater elements are configured in a serpentine or spiral fashion.

32. An evaporation source according to claim 1, wherein said radiant resistive heater elements are made from Tungsten (W) wire.

33. An evaporation source according to claim 32, wherein said radiant resistive heater elements are configured in a serpentine or spiral fashion.

34. An evaporation source according to claim 1, wherein said radiant resistive heater elements are made from W foil.

35. An evaporation source according to claim 34, wherein said radiant resistive heater elements are configured in a serpentine or spiral fashion.

36. An evaporation source according to claim 1, wherein said radiant resistive heater elements are made from Tantalum (Ta) wire.

37. An evaporation source according to claim 36, wherein said radiant resistive heater elements are configured in a serpentine or spiral fashion.

38. An evaporation source according to claim 1, wherein said radiant resistive heater elements are made from Ta foil.

39. An evaporation source according to claim 38, wherein said radiant resistive heater elements are machined in a serpentine or spiral fashion.

40. An evaporation source according to claim 1, wherein the position of said piston in said reservoir is manually set.

41. An evaporation source according to claim 40, wherein said position is set using a micrometer screw attached to said linear motion vacuum feedthrough attached to a shaft driving said piston.

42. An evaporation source according to claim 41, wherein the position is set using a motor to drive said micrometer screw.

43. An evaporation source according to claim 1, wherein the position of said piston in said reservoir is automatically adjusted.

44. An evaporation source according to claim 43, wherein the position of said piston is automatically adjusted using an electronic feedback control circuit.

45. An evaporation source according to claim 44, wherein said electronic feedback control circuit senses the electrical contact resistance between said liquid metal and said conducting probes.

46. An evaporation source according to claim 45, wherein said electronic feedback control circuit applies power to a motor that drives a micrometer screw attached to said linear motion vacuum feedthrough attached to a shaft driving said piston.

47. An evaporation source according to claim 1, wherein said refractory material for said source is chosen not to react with said liquid metal at temperatures required to achieve evaporation of said liquid metal.

48. An evaporation source according to claim 1, wherein said liquid metal is selected from the group consisting of Silver (Ag), Aluminum (Al), Gold (Au), Boron (B), Barium (Ba), Bismuth (Bi), Cadmium (Cd), Cobolt (Co), Cesium (Cs), Copper (Cu), Iron (Fe), Gallium (Ga), Gadolinium (Gd), Germanium (Ge), Mercury (Hg), Indium (In), Potassium (K), Lanthanum (La), Lithium (Li), Sodium (Na), Nickel (Ni), Lead (Pb), Palladium (Pd), Praseodymium (Pr), Platinum (Pt), Rubidium (Rb), Antimony (Sb), Scandium (Sc), Selenium (Se), Silicon (Si), Tin (Sn), Tellurium (Te), Thallium (Tl), Vanadium (V), Ytterbium (Y), and Zinc (Zn).

49. A liquid metal evaporation source for use in Molecular Beam Epitaxy (MBE) or vacuum deposition processes, said evaporation source comprising:
a first zone maintained at a first temperature;
a second zone maintained at a second temperature; and
a third zone maintained at a third temperature;
wherein each of said first, second and third zones include a heater means for sensing and regulating said first, second and third temperatures, and
wherein said first, second and third zones are in fluid communication.

50. A liquid metal evaporation source according to claim 49, wherein said first zone includes an evaporator, said second zone includes a hollow transport tube, and said third zone includes a reservoir with a close-mating piston.

51. A liquid metal evaporation source according to claim 50, wherein at least one of said evaporator, said hollow transport tube and said reservoir is made from refractory material.

52. An evaporation source according to claim 51, wherein said refractory material is densified graphite.

53. An evaporation source according to claim 52, wherein said refractory material does not react with said liquid metal at temperatures required for evaporation of said liquid metal.

54. An evaporation source according to claim 51, wherein at least one of said evaporator, said hollow transport tube and said reservoir is coated with a layer of material selected from the group consisting of Pyrolytic Graphite (PG), Pyrolytic Boron Nitride (PBN), Pyrolytic Silicon Carbide (PSiC), and Pyrolytic Aluminum Nitride (PAN).

55. A liquid metal evaporation source according to claim 50, wherein said evaporation source includes at least one conducting probe used to sense contact with liquid metal in said evaporator.

56. An evaporation source according to claim 55, wherein at least one of said conducting probes is made from a non-reacting refractory material.

57. An evaporation source according to claim 56, wherein said non-reacting refractory material is densified graphite.

58. An evaporation source according to claim 57, wherein said conducting probes are insulated from each other and insulated from the walls of said evaporator.

59. An evaporation source according to claim 58, wherein ceramic coating is said insulator.

60. An evaporation source according to claim 58, wherein said ceramic coating is made from pyrolytic boron nitride (PBN).

61. An evaporation source according to claim 60, wherein at least one of said conducting probes is positioned above the surface of said liquid metal.

62. An evaporation source according to claim 60, wherein at least one of said conducting probes is inserted from below the surface of said liquid metal through said evaporator.

63. An evaporation source according to claim 55, wherein at least one of said conducting probes makes a first contact with said liquid metal on its surface and makes a second contact with said liquid metal through conductive walls of said evaporator.

64. A liquid metal evaporation source according to claim 63, wherein said at least one conducting probe controls the position of said piston via an automatic feedback control circuit.

65. A liquid metal evaporation source according to claim 64, wherein said automatic feedback control circuit drives a motor attached to said piston and regulates a constant height of said liquid metal in said evaporator.

66. An evaporation source according to claim 50, wherein at least one of said evaporator, said hollow transport tube, and said reservoir are made from a single piece of refractory material in essentially a concentric configuration.

67. An evaporation source according to claim 50, wherein said evaporator and said hollow transport tube are joined at a right angle to the axis of said reservoir by leak-tight flat flanges.

68. An evaporation source according to claim 67, wherein said evaporation source includes a co-joining passageway for said liquid metal between said reservoir and said hollow transport tube.

69. An evaporation source according to claim 67, wherein said leak-tight flat flanges are attached using threaded assemblies.

70. An evaporation source according to claim 67, wherein said leak-tight flat flanges are attached using refractory clamps.

71. An evaporation source according to claim 70, wherein said refractory clamps are joined using refractory nuts and bolts.

72. An evaporation source according to claim 50, wherein said evaporator and said hollow transport tube are joined at an angle in the range of 0 to 180 degrees to said reservoir along its axis by leak-tight flanges.

73. An evaporation source according to claim 72, wherein said evaporation source includes a co-joining passageway for said liquid metal between said reservoir and said hollow transport tube.

74. An evaporation source according to claim 72, wherein said leak-tight flat flanges are attached using threaded assemblies.

75. An evaporation source according to claim 72, wherein said leak-tight flat flanges are attached using refractory clamps.

76. An evaporation source according to claim 75, wherein said refractory clamps are joined together using refractory nuts and bolts.

77. An evaporation source according to claim 50, wherein said evaporator includes an evaporator nosecone.

78. An evaporation source according to claim 77, wherein said evaporator nosecone is configured to a shape suitable for providing a metal beam flux profile incident upon a substrate.

79. A liquid metal evaporation source according to claim 49, wherein said first temperature is higher than said second temperature.

80. A liquid metal evaporation source according to claim 48, wherein said second temperature is higher than said third temperature.

81. An evaporation source according to claim 49, wherein said heater means is made from refractory materials.

82. An evaporation source according to claim 81, wherein said heater means is configured in a serpentine or spiral fashion.

83. An evaporation source according to claim 49, wherein said heater means is densified graphite.

84. An evaporation source according to claim 49, wherein said heater means is made from Tungsten (W) wire.

85. An evaporation source according to claim 84, wherein said heater means is configured in a serpentine or spiral fashion.

86. An evaporation source according to claim 49, wherein said heater means is made from W foil.

87. An evaporation source according to claim 86, wherein said heater means is configured in a serpentine or spiral fashion.

88. An evaporation source according to claim 49, wherein said heater means is made from Tantalum (Ta) wire.

89. An evaporation source according to claim 88, wherein said heater means is configured in a serpentine or spiral fashion.

90. An evaporation source according to claim 49, wherein said heater means is made from Ta foil.

91. An evaporation source according to claim 90, wherein said heater means is configured in a serpentine or spiral fashion.

92. An evaporation source according to claim 50, wherein the position of said piston in said reservoir is manually set.

93. An evaporation source according to claim 92, wherein said position is set using a micrometer screw attached to said linear motion vacuum feedthrough attached to a shaft driving said piston.

94. An evaporation source according to claim 93, wherein the position is set using a motor to drive said micrometer screw.

95. An evaporation source according to claim 50, wherein the position of said piston in said reservoir is automatically adjusted.

96. An evaporation source according to claim 95, wherein the position of said piston is automatically adjusted using an electronic feedback control circuit.

97. An evaporation source according to claim 96, wherein said electronic feedback control circuit senses the electrical contact resistance between said liquid metal and said conducting probes.

98. An evaporation source according to claim 97, wherein said electronic feedback control circuit applies power to a motor that drives a micrometer screw attached to said linear motion vacuum feedthrough attached to a shaft driving said piston.

99. An evaporation source according to claim 51, wherein said refractory material for said source is chosen not to react with said liquid metal at temperatures required to achieve evaporation of said liquid metal.

100. An evaporation source according to claim 49, wherein said liquid metal is selected from the group consisting of Silver (Ag), Aluminum (Al), Gold (Au), Boron (B), Barium (Ba), Bismuth (Bi), Cadmium (Cd), Cobolt (Co), Cesium (Cs), Copper (Cu), Iron (Fe), Gallium (Ga), Gadolinium (Gd), Germanium (Ge), Mercury (Hg), Indium (In), Potassium (K), Lanthanum (La), Lithium (Li), Sodium (Na), Nickel (Ni), Lead (Pb), Palladium (Pd), Praseodymium (Pr), Platinum (Pt), Rubidium (Rb), Antimony (Sb), Scandium (Sc), Selenium (Se), Silicon (Si), Tin (Sn), Tellurium (Te), Thallium (Tl), Vanadium (V), Ytterbium (Y), and Zinc (Zn).

101. A liquid metal evaporation source for use in Molecular Beam Epitaxy (MBE) or vacuum deposition processes, said evaporation source comprising:
an evaporator;
a transport tube; and
a reservoir with close-mating piston;
wherein each of said evaporator, said transport tube and said reservoir include a heater element having a thermocouple for sensing and regulating the temperature, and
wherein said evaporator, said transport tune and said reservoir are in fluid communication.

102. A liquid metal evaporation source according to claim 101, wherein said evaporator is maintained at a high temperature.

103. A liquid metal evaporation source according to claim 101, wherein said transport tube is maintained at a temperature lower than said evaporator.

104. A liquid metal evaporation source according to claim 101, wherein said reservoir is maintained at a lower temperature than said transport tube.

105. A liquid metal evaporation source according to claim 101, wherein at least one of said evaporator, said transport tube and said reservoir is made from refractory material.

106. An evaporation source according to claim 101, wherein said refractory material is densified graphite.

107. An evaporation source according to claim 105, wherein said refractory material does not react with said liquid metal at temperatures required for evaporation of said liquid metal.

108. An evaporation source according to claim 101, wherein at least one of said evaporator, said transport tube and said reservoir is coated with a layer of material selected from the group consisting of Pyrolytic Graphite (PG), Pyrolytic Boron Nitride (PBN), Pyrolytic Silicon Carbide (PSiC), and Pyrolytic Aluminum Nitride (PAN).

109. A liquid metal evaporation source according to claim 101, wherein said evaporation source includes at least one conducting probe used to sense contact with liquid metal in said evaporator.

110. An evaporation source according to claim 109, wherein at least one of said conducting probes is made from a non-reacting refractory material.

111. An evaporation source according to claim 110, wherein said non-reacting refractory material is densified graphite.

112. An evaporation source according to claim 111, wherein said conducting probes are insulated from each other and insulated from the walls of said evaporator.

113. An evaporation source according to claim 112, wherein ceramic coating is said insulator.

114. An evaporation source according to claim 113, wherein said ceramic coating is made from pyrolytic boron nitride (PBN).

115. An evaporation source according to claim 109, wherein at least one of said conducting probes is positioned above the surface of said liquid metal.

116. An evaporation source according to claim 109, wherein at least one of said conducting probes is inserted from below the surface of said liquid metal through said evaporator.

117. An evaporation source according to claim 109, wherein at least one of said conducting probes makes a first contact with said liquid metal on its surface and makes a second contact with said liquid metal through conductive walls of said evaporator.

118. A liquid metal evaporation source according to claim 109, wherein said at least one conducting probe controls the position of said piston via an automatic feedback control circuit.

119. A liquid metal evaporation source according to claim 118, wherein said automatic feedback control circuit drives a motor attached to said piston and regulates a constant height of said liquid metal in said evaporator.

120. An evaporation source according to claim 101, wherein at least one of said evaporator, said transport tube, and said reservoir are made from a single piece of refractory material in essentially a concentric configuration.

121. An evaporation source according to claim 101, wherein said evaporator and said transport tube are joined at a right angle to the axis of said reservoir by leak-tight flat flanges.

122. An evaporation source according to claim 121, wherein said evaporation source includes a co-joining passageway for said liquid metal between said reservoir and said transport tube.

123. An evaporation source according to claim 121, wherein said leak-tight flat flanges are attached using threaded assemblies.

124. An evaporation source according to claim 121, wherein said leak-tight flat flanges are attached using refractory clamps.

125. An evaporation source according to claim 124, wherein said refractory clamps are joined using refractory nuts and bolts.

126. An evaporation source according to claim 101, wherein said evaporator and said transport tube are joined at an angle in the range of 0 to 180 degrees to said reservoir along its axis by leak-tight flanges.

127. An evaporation source according to claim 126, wherein said evaporation source includes a co-joining passageway for said liquid metal between said reservoir and said transport tube.

128. An evaporation source according to claim 126, wherein said leak-tight flat flanges are attached using threaded assemblies.

129. An evaporation source according to claim 126, wherein said leak-tight flat flanges are attached using refractory clamps.

130. An evaporation source according to claim 129, wherein said refractory clamps are joined together using refractory nuts and bolts.

131. An evaporation source according to claim 101, wherein said evaporator includes an evaporator nosecone.

132. An evaporation source according to claim 131, wherein said evaporator nosecone is configured to a shape suitable for providing a metal beam flux profile incident upon a substrate.

133. An evaporation source according to claim 101, wherein said heater means is made from refractory materials.

134. An evaporation source according to claim 133, wherein said heater means is densified graphite.

135. An evaporation source according to claim 134, wherein said heater means is configured in a serpentine or spiral fashion.

136. An evaporation source according to claim 101, wherein said heater means is made from Tungsten (W) wire.

137. An evaporation source according to claim 136, wherein said heater means is configured in a serpentine or spiral fashion.

138. An evaporation source according to claim 101, wherein said heater means is made from W foil.

139. An evaporation source according to claim 138, wherein said heater means is configured in a serpentine or spiral fashion.

140. An evaporation source according to claim 101, wherein said heater means is made from Tantalum (Ta) wire.

141. An evaporation source according to claim 140, wherein said heater means is configured in a serpentine or spiral fashion.

142. An evaporation source according to claim 101, wherein said heater means is made from Ta foil.

143. An evaporation source according to claim 142, wherein said heater means is configured in a serpentine or spiral fashion.

144. An evaporation source according to claim 101, wherein the position of said piston in said reservoir is manually set.

145. An evaporation source according to claim 144, wherein said position is set using a micrometer screw attached to said linear motion vacuum feedthrough attached to a shaft driving said piston.

146. An evaporation source according to claim 145, wherein the position is set using a motor to drive said micrometer screw.

147. An evaporation source according to claim 101, wherein the position of said piston in said reservoir is automatically adjusted.

148. An evaporation source according to claim 147, wherein the position of said piston is automatically adjusted using an electronic feedback control circuit.

149. An evaporation source according to claim 148, wherein said electronic feedback control circuit senses the electrical contact resistance between said liquid metal and said conducting probes.

150. An evaporation source according to claim 149, wherein said electronic feedback control circuit applies power to a motor that drives a micrometer screw attached to said linear motion vacuum feedthrough attached to a shaft driving said piston.

151. An evaporation source according to claim 101, wherein said refractory material for said source is chosen not to react with said liquid metal at temperatures required to achieve evaporation of said liquid metal.

152. An evaporation source according to claim 101, wherein said liquid metal is selected from the group consisting of Silver (Ag), Aluminum (Al), Gold (Au), Boron (B), Barium (Ba), Bismuth (Bi), Cadmium (Cd), Cobolt (Co), Cesium (Cs), Copper (Cu), Iron (Fe), Gallium (Ga), Gadolinium (Gd), Germanium (Ge), Mercury (Hg), Indium (In), Potassium (K), Lanthanum (La), Lithium (Li), Sodium (Na), Nickel (Ni), Lead (Pb), Palladium (Pd), Praseodymium (Pr), Platinum (Pt), Rubidium (Rb), Antimony (Sb), Scandium (Sc), Selenium (Se), Silicon (Si), Tin (Sn), Tellurium (Te), Thallium (Ti), Vanadium (V), Ytterbium (Y), and Zinc (Zn).
